(19) United States
(12) Patent Application Publication
(10) Pub. No.: US 2004/0004475 A1
(43) Pub. Date: Jan. 8, 2004

(54) High throughput absolute flaw imaging

(75) Inventors: Neil J. Goldfine, Newton, MA (US); Vladimir A. Zilberstein, Chestnut Hill, MA (US); J. Stephen Cargill, Hobe Sound, FL (US); Darrell E. Schlicker, Watertown, MA (US); Ian C. Shay, Cambridge, MA (US); Andrew P. Washabaugh, Chula Vista, CA (US); Vladimir Tsukernik, West Roxbury, MA (US); David C. Grundy, Reading, MA (US); Mark D. Windoloski, Burlington, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: JENTEK Sensors, Inc., Waltham, MA

(21) Appl. No.: 10/419,702

(22) Filed: Apr. 18, 2003

Related U.S. Application Data
(60) Provisional application No. 60/374,671, filed on Apr. 22, 2002.

(51) Int. Cl. G01N 27/90; G01R 33/12

(52) U.S. Cl. 324/242; 324/240

(57) ABSTRACT

Apparatus and methods are described for the improved throughput and increased reliability for inspection of critical surfaces on aircraft engine disks. Eddy current sensor arrays allow two-dimensional images to be generated for detection of cracks in regions with fretting damage. Background variations due to fretting damage and stress variations are also accommodated. These arrays are combined with instrumentation that permits parallel data acquisition for each sensing element and rapid inspection rates. Inflatable support structures behind the sensor array improve sensor durability and reduce fixturing requirements for the inspection.

### RELATED APPLICATION(S)

This application claims the benefit of U.S. Provisional Application No. 60/374,671, filed Apr. 22, 2002. The entire teachings of the above application(s) are incorporated herein by reference.

### GOVERNMENT SUPPORT

The invention was supported, in whole or in part, by a grant F33615-97-D-5271 from the Air Force. The Government has certain rights in the invention.

### BACKGROUND OF THE INVENTION

The technical field of this invention is that of nondestructive materials characterization, particularly quantitative, model-based characterization of surface, near-surface, and bulk material condition for flat and curved parts or components using magnetic field based or eddy-current sensors. Characterization of bulk material condition includes (1) measurement of changes in material state, i.e., degradation/damage caused by fatigue damage, creep damage, thermal exposure, or plastic deformation; (2) assessment of residual stresses and applied loads; and (3) assessment of processing-related conditions, for example from aggressive grinding, shot peening, roll burnishing, thermal-spray coating, welding or heat treatment. It also includes measurements characterizing material, such as alloy type, and material states, such as porosity and temperature. Characterization of surface and near-surface conditions includes measurements of surface roughness, displacement or changes in relative position, coating thickness, temperature and coating condition. Each of these includes detection of electromagnetic property changes associated with either microstructural and/or compositional changes, or electronic structure (e.g., Fermi surface) or magnetic structure (e.g., domain orientation) changes, or with single or multiple cracks.

A specific application of these techniques is the inspection of engine disks for cracks in regions with fretting damage. This has become a recent focus of military aircraft engine disk inspection research. Inspections performed by automated eddy current inspection methods, for example at the U.S. Air Force's Retirement for Cause (RFC) facilities, have generally addressed scheduled inspections of surfaces that do not experience significant fretting damage. For such relatively smooth surfaces, probability of detection (POD) studies have been devised to ensure reliable detection of relevant cracks, as described in MIL-HDBK-1823 (1999). These studies use Engine Structural Integrity Program (ENSIP) specimens with a statistically significant number of cracks to demonstrate and test reliability of eddy current testing methods. To ensure that the automated scanning (scan path) covers the required critical regions of an engine disk during inspections, these studies also use disk specimens with simulated cracks located near the boundaries of critical zones.

For inspection calibrations, simulated cracks and embedded wire standards are used. Embedded wire standards are commercially pure copper wires embedded in silicon nitride blocks. They are used during periodic system calibrations of conventional eddy current sensors to assure consistent overall sensitivity of inspection where the reliable detection of relatively small cracks, e.g., 0.125 mm to 0.4 mm (0.005 to 0.015 in.) deep and 0.25 mm to 0.75 mm (0.01 to 0.03 in.) long with length to depth ratios between 1:1 and 3:1 has been the focus. These scheduled inspections are generally performed in regions without fretting damage. However, some regions within a disk slot may have significant fretting damage that degrades the capabilities of conventional eddy current testing methods, e.g., potentially causing an unacceptably high number of false positive detections. The regions with fretting damage tend to have clusters of small cracks that link up (coalesce) to form long shallow cracks (with length to depth aspect ratios of 4:1 to more than 10:1). These crack formations are not well represented by available ENSIP flat specimens. For the fretting regions, unscheduled inspections have been developed using ultrasonic testing (UT). In some cases, the UT can only provide reliable detection of shallow cracks in fretting damage regions when they are at least 3.75 mm (0.15 in.) long. Conventional eddy current testing might produce excessive false positive indications when inspecting relatively rough surfaces such as surfaces with fretting damage.

Conventional eddy-current sensing involves the excitation of a conducting winding, the primary, with an electric current source of prescribed frequency. This produces a time-varying magnetic field at the same frequency, which in turn is detected with a sensing winding, the secondary. The spatial distribution of the magnetic field and the field measured by the secondary is influenced by the proximity and physical properties (electrical conductivity and magnetic permeability) of nearby materials. When the sensor is intentionally placed in close proximity to a test material, the physical properties of the material can be deduced from measurements of the impedance between the primary and secondary windings. Traditionally, scanning of eddy-current sensors across the material surface is then used to detect flaws, such as cracks.

For engine disk slot inspection, differential coil designs are typically used. These designs sense local changes in the flow of eddy currents by comparing signals in neighboring regions. For clusters of cracks, this “comparison” could occur between a sensing region on a large crack and one on a neighboring small crack or cluster of small cracks. This could significantly alter (reduce) the differential signal. Furthermore, differential coil designs are affected by local changes in proximity between the two sensed regions, e.g., if one region of a differential coil is at a different lift-off than the other.

### SUMMARY OF THE INVENTION

Aspects of the invention described herein involve sensors and sensor arrays for the measurement of the near surface properties of conducting and/or magnetic materials. These sensors and arrays use adapted geometries for the primary winding and sensing elements that promote accurate modeling of the response and provide enhanced capabilities for the creation of images of the properties of a test material.

In one embodiment of the invention, test material surfaces can be rapidly inspected by using at least one row of sensing elements, individual connections to each sensing element, an instrument for measuring the response of each sense element essentially simultaneously, an encoder for providing the sensor position over the test materials and means for converting the measured response into a material or geometric property. Performing the data acquisition in parallel permits rapid scanning of the sensor over the surface without loss of data quality. A primary winding for creating the magnetic field that couples to the sense elements through the test material may be in the same plane as the sense elements, or in different planes. In an embodiment, the sense elements are rectangular coils. In another embodiment, the difference in responses is measured between the sense element and a pair of conductors that closely parallel the connection leads to the sense elements, which allows the connector lead response to be subtracted from the sense element response. A second row of sense elements on the opposite side of the primary winding conductor can also be used, which provides complementary information about any property variations or flaws within the test material.

In another embodiment, a pressurizable or inflatable support is placed behind the sensor array. The support may have both flexible and rigid components and allows the flexible sensor to substantially conform to the surface of the test material. By deflating the support prior to inserting the sensor into the test material surface, such as an engine disk slot, and then re-inflating prior to the measurement scan, damage to the sensor can be reduced so that it the inspection system is more durable.

For many materials, such as engine disk slots, the inspection can require the detection of cracks in regions of fretting damage. In one embodiment, the primary conductors are oriented perpendicular to the likely crack orientation, which is the direction of maximum sensitivity to the presence of cracks. In another embodiment, the primary conductors are oriented at an acute angle with the likely crack direction. In another embodiment, the material is scanned multiple times with the primary conductors oriented at different angles, preferably between −45° and 30° with respect to the likely crack direction, to ensure maximal detectability for any crack orientation. In a further embodiment, the sensor array has at least two rows of sensing elements oriented at different angles to the scan direction so that a multiple-angled inspection can be performed in single pass.

Effective properties obtained with these measurements are, in one embodiment, the electrical conductivity of the material, and, in another embodiment, the lift-off of each sense element. In other embodiments these effect properties are correlated with features of the flaw or crack, such as the crack length or crack location. In another embodiment, the response to a crack can be enhanced by processing with a filter that compares the effective property response with a known shape response for a specific flaw. Furthermore, multiple frequency measurements can be performed to separate the flaw response from background variations, or to better characterize the shape or size of a detected flaw.

In another embodiment, calibration is performed by measuring the response of the sensor on a nonconducting material, such as air. Furthermore, the calibration can also include measurements of the response of a shunt sensor that has the leads to the sensing elements shorted together. This permits a better compensation for the effects of the connection leads themselves. Preferably, this shunt measurement is performed on the test material to mimic the inspection conditions as well as possible. In an embodiment, both the sensor and shunt measurement are performed on an insulating solid so that any flexing of the leads to the sensing elements is the same for the calibration measurements.

In another embodiment, the sensor array is scanned along one side of a concave opening to image the material properties. Complete coverage of the opening can be ensured by flipping the component over, so that the other side of the opening can also be scanned, or by locating sense elements completely around the sides of the opening.

In one embodiment, the statistics on the background variation or noise is used along with parametric or other model estimates of background noise with signature response for the flaws to set threshold levels for the inspection. The flaws are typically cracks and the signature responses can be from actual, service-run, cracks or simulated cracks. In this manner the threshold levels are based on prior experience. The background variations of the test material can be based on calibration measurements or a standardization measurement performed prior to the inspection.

In one embodiment, a design for an eddy current sensor array is disclosed that allows the material interactions with two orientations of the magnetic field to be monitored in a single pass of the sensor over the he material surface. The sensing elements may be on the same plane as the drive winding or in different planes. The sensor array can be mounted onto a flexible substrate to facilitate conformability of the sensor with the test material surface.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a drawing of a spatially periodic field eddy-current sensor.

FIG. 2 is an expanded view of the drive and sense elements for an eddy-current array having offset rows of sensing elements.

FIG. 3 is an expanded view of the drive and sense elements for an eddy-current array having a single row of sensing elements.

FIG. 4 is an expanded view of an eddy-current array where the locations of the sensing elements along the array are staggered.

FIG. 5 is an expanded view of an eddy current array with a single rectangular loop drive winding and a linear row of sense elements on the outside of the extended portion of the loop.

FIG. 6 is a pictorial cross-sectional view of some of the drive and sense elements for a sensor array.

FIG. 7 is a plot of the depth of penetration for a typical titanium or nickel alloy with assumed conductivity of 1 MS/m (1.72% IACS), as a function of temporal frequency and MWM spatial wavelength.

FIG. 8 shows a representative measurement grid relating the magnitude and phase of the sensor terminal impedance to the lift-off and electrical conductivity.

FIG. 9 shows a representative measurement grid relating the magnitude and phase of the sensor terminal impedance to the lift-off and electrical conductivity.

FIG. 10 is a drawing of a probe for inspection of engine disk slots.

FIG. 11 shows two-dimensional MWM-Array conductivity images for Slots 2 through 5. Note that the 0.38-mm (0.015-in.) long crack in Slot 4 is not apparent with the image color scale.

FIG. 12 shows two-dimensional MWM-Array conductivity images for Slots 6 through 9. Note the large crack in Slot 9 is listed with the apparent (4 mm) and total length where the latter includes a tight 1 mm extension barely detectable on the replica in a microscope, even at 100×. The details of the other, smaller crack located at position 0.82 in Slot 9 were not initially recorded.

FIG. 13 shows an expanded view of the edge of the slot from the MWM-Array conductivity images and indicates the effective width of the edge signature. The MWM-Array sensing element size is also indicated.

FIG. 14 shows a single-channel (sensing element) conductivity plot for the element crossing the crack for Slot 2.

FIG. 15 shows a single-channel (sensing element) conductivity plot for the element crossing the crack for Slot 5.

FIG. 16 shows a single-channel (sensing element) conductivity plot for the element crossing the crack for Slot 9.

FIG. 17 shows an expanded view of the single-channel (sensing element) conductivity plot for the element crossing the crack for Slot 9 to show the presence of the smaller crack.

FIG. 18 shows some crack length estimation results. The results are plotted in inches (1 in.=25.4 mm). Note that the 5 mm (0.2 in.) long crack was comprised of a 4 mm (0.16 in.) long segment and a 1 mm (0.04-in.) very tight crack extension that is barely visible on the replica when viewed in a microscope, and was not captured in the photographs). The 4-mm (0.16-in.) length for this crack provides a better agreement with the MWM-Array length estimate.

FIG. 19 shows crack location estimates, in terms of distance from the slot edge to the crack tip, for the crack nearest the edge in each of Slots 2, 5, 6, 8, and 9. The distances are plotted in inches (1 in.=25.4 mm).

FIG. 20 shows POD curves generated from crack response data on ENSIP-type flat specimens.

FIG. 21 is an expanded view of an eddy current array with a single rectangular loop drive winding and a linear row of sense elements on the outside of the extended portion of the loop.

FIG. 22 is an expanded view of another eddy current array with a single rectangular loop drive winding and a linear row of sense elements.

FIG. 23 is a plot of relative permeability variation with frequency for a material having a stressed region near the surface that affects the magnetic permeability of the material.

FIG. 24 is a plot of relative permeability variation with depth for a material having a stressed region near the surface that affects the magnetic permeability of the material.

FIG. 25 is a plot of relative permeability variation with stress.

FIG. 26 is a drawing of an alternative sensor array design containing sense elements at two different angles.

### DETAILED DESCRIPTION OF THE INVENTION

A description of preferred embodiments of the invention follows.

The use of conformable eddy-current sensors and sensor arrays is described for the nondestructive characterization of materials, particularly as it applies to the detection of cracks in regions with fretting damage. These flexible eddy current sensors can provide absolute property measurements and high-resolution two-dimensional (C-scan) images of cracks in engine disk slots when configured into arrays. These inspections can be achieved with automated and manual scanning for detection of cracks, without the use of crack standards for calibration. Calibration is performed in air or on a non-conducting material and detection thresholds are set based on prior experience and background noise including material property variations. Robustness is achieved using model-based methods. Specimens with known crack sites can be used for occasional performance verification, but are not required for calibration. The sensors described here use absolute sensing elements to overcome the limitations of differential coil designs, both to avoid comparison of neighboring regions that might contain cracks and to provide robust correction for lift-off variations, e.g., caused by fretting damage.

A conformable eddy-current sensor suitable for these inspections, the Meandering Winding Magnetometer (MWM®), is described in U.S. Pat. Nos. 5,015,951, 5,453,689, and 5,793,206. The MWM is a “planar,” conformable eddy-current sensor that was designed to support quantitative and autonomous data interpretation methods. These methods, called grid measurement methods, permit crack detection on curved surfaces without the use of crack standards, and provide quantitative images of absolute electrical properties (conductivity and permeability) and coating thickness without requiring field reference standards (i.e., calibration is performed in “air,” away from conducting surfaces). MWM sensors and MWM-Arrays can be used for a number of applications, including fatigue monitoring and inspection of components for detection of flaws, degradation and microstructural variations as well as for characterization of coatings, process-induced surface layers, and stresses. Characteristics of these sensors and sensor arrays include directional multi-frequency electrical conductivity or magnetic permeability measurements over a wide range of frequencies, e.g., from 100 Hz to 40 MHz with the same MWM sensor or MWM-Array, high-resolution imaging of measured conductivity or permeability, rapid conductivity or permeability measurements with or without a contact with the surface, and a measurement capability on complex surfaces with a hand-held probe or with an automated scanner. This allows the assessment of crack presence and size over smooth and fretted surfaces having simple or complex geometry.

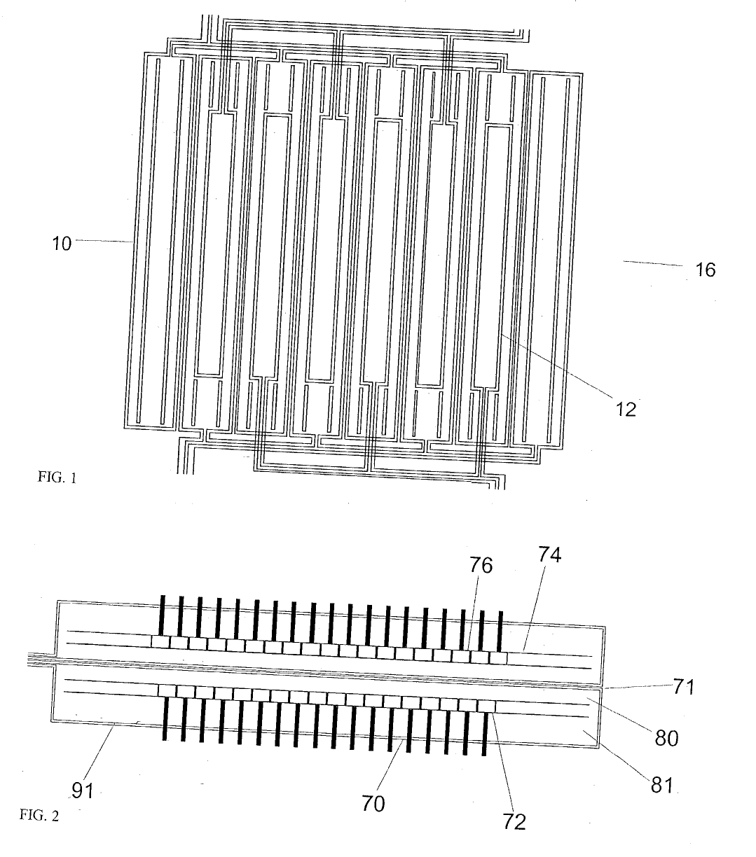

FIG. 1 illustrates the basic geometry of an the MWM sensor 16, a detailed description of which is given in U.S. Pat. Nos. 5,453,689, 5,793,206, and 6,188,218 and U.S. patent application Ser. Nos. 09/666,879 and 09/666,524, both filed on Sep. 20, 2000, the entire teachings of which are incorporated herein by reference. The sensor includes a primary winding 10 having extended portions for creating the magnetic field and secondary windings 12 within the primary winding for sensing the response. The primary winding is fabricated in a spatially periodic pattern with the dimension of the spatial periodicity termed the spatial wavelength λ. A current is applied to the primary winding to create a magnetic field and the response of the MUT to the magnetic field is determined through the voltage measured at the terminals of the secondary windings. This geometry creates a magnetic field distribution similar to that of a single meandering winding. A single element sensor has all of the sensing elements connected together. The magnetic vector potential produced by the current in the primary can be accurately modeled as a Fourier series summation of spatial sinusoids, with the dominant mode having the spatial wavelength λ. For an MWM-Array, the responses from individual or combinations of the secondary windings can be used to provide a plurality of sense signals for a single primary winding construct as described in U.S. Pat. No. 5,793,206 and Re. 36,986.

In operation, the drive windings for the sensors are excited with a current at a prescribed frequency, for magnetoquasistatic (MQS) inspection of metals. When interrogating a conducting material, for example, in an aircraft engine disk slot or bolt hole, the current in the drive produces a time varying magnetic field that induces eddy currents in the material under test. These induced eddy currents within the metal follow the same path as the linear drive segments. In other words, the eddy current pattern, induced in the material under test, looks like a reflected image of the drive winding geometry. When a crack, corrosion damage, an inclusion, surface roughness, local residual or applied stress change, or an internal geometric feature alters the flow of these eddy currents, then the inductive sensing coils sense an absolute magnetic field that is altered locally by the presence of the crack, other damage, or material property variation. The use of absolute inductive sensing coils, instead of differential sensing coils, permits the use of models based on physical principles to analyze the data. For example, the goal might be to measure the sensor proximity to the surface, called the lift-off, at each sensing element and the electrical conductivity of the material along the path of the induced eddy currents. A model-based inversion then permits, for example, independent conductivity and lift-off measurements. Conventional eddy current sensors with absolute or differential elements empirically correct for lift-off instead of using a physical model.

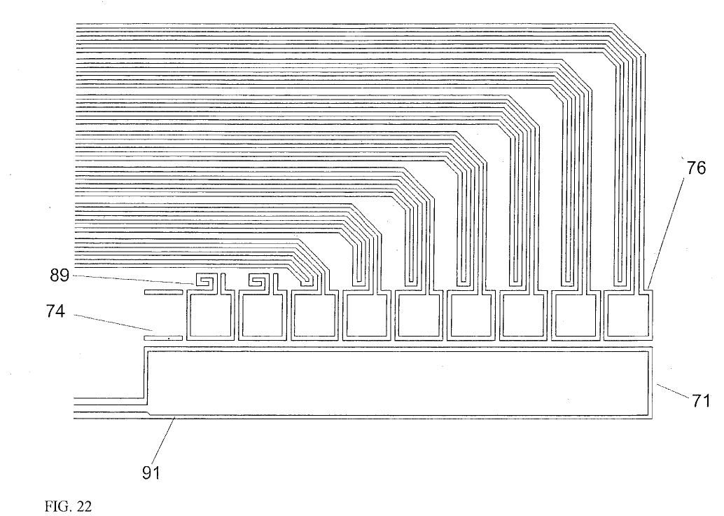

Eddy-current sensor arrays comprised of at least one meandering drive winding and multiple sensing elements can also be used to inspect the test material. Example sensor arrays are shown in FIG. 2 through FIG. 5, FIG. 21, and FIG. 22 and are described in detail in U.S. patent application Ser. No. 10/102,620, filed Mar. 19, 2002, the entire teachings of which are incorporated herein by reference. This array includes a primary winding 70 having extended portions for creating the magnetic field and a plurality of secondary elements 76 within the primary winding for sensing the response to the MUT. The secondary elements are pulled back from the connecting portions of the primary winding to minimize end effect coupling of the magnetic field. Dummy elements 74 can be placed between the meanders of the primary to maintain the symmetry of the magnetic field, as described in U.S. Pat. No. 6,188,218. When the sensor is scanned across a part or when a crack propagates across the sensor, perpendicular to the extended portions of the primary winding, secondary elements 72 in a primary winding loop adjacent to the first array of sense elements 76 provide a complementary measurement of the part properties. These arrays of secondary elements 72 can be aligned with the first array of elements 76 so that images of the material properties will be duplicated by the second array. Alternatively, to provide complete coverage when the sensor is scanned across a part the sensing elements, can be offset along the length of the primary loop or when a crack propagates across the sensor, perpendicular to the extended portions of the primary winding, as illustrated in FIG. 2.

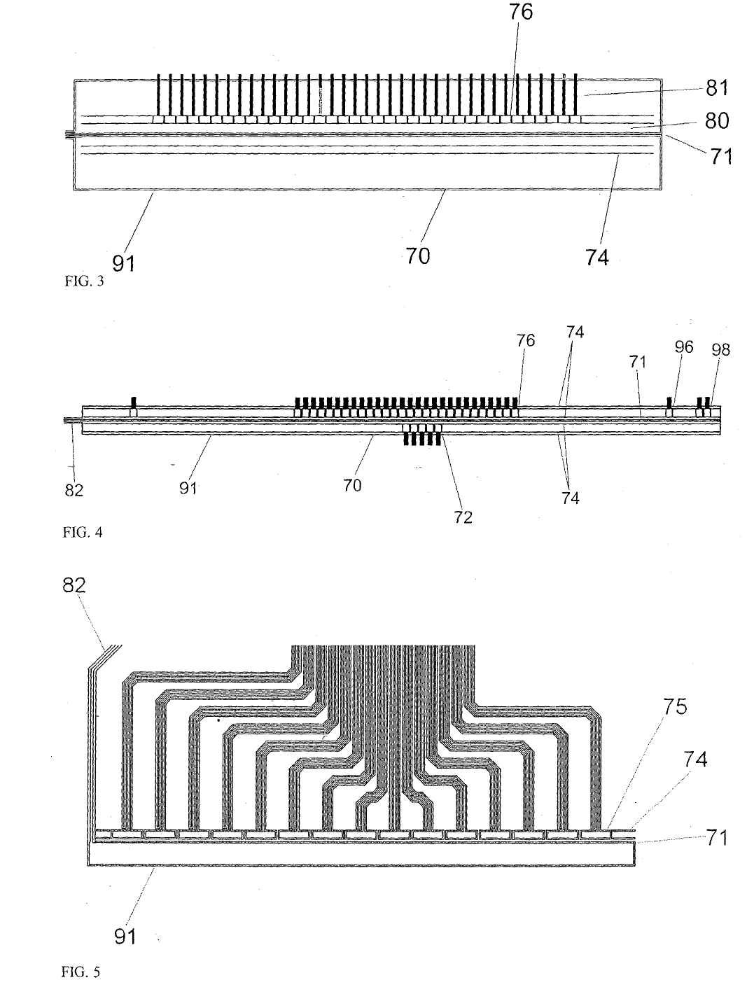

The dimensions for the sensor array geometry and the placement of the sensing elements can be adjusted to improve sensitivity for a specific inspection. For example, the effective spatial wavelength or the distance between the central conductors 71 and the current return conductor 91 can be altered to adjust the sensitivity of a measurement for a particular inspection. For the sensor array of FIG. 2, the distance 80 between the secondary elements 72 and the central conductors 71 is smaller than the distance 81 between the sensing elements 72 and the return conductor 91. An optimum response can be determined with models, empirically, or with some combination of the two. An example of a modified sensor design is shown FIG. 3. In this sensor array, all of the sensing elements 76 are on one side of the central drive windings 71. The size of the sensing elements and the gap distance 80 to the central drive windings 71 are the same as in the sensor array of FIG. 2. However, the distance 81 to the return of the drive winding has been increased, as has the drive winding width to accommodate the additional elements in the single row of elements. Another example of a modified design is shown in FIG. 4. Here, most of the sensing elements 76 are located in a single row to provide the basic image of the material properties. A small number of sensing elements 72 are offset from this row to create a higher image resolution in a specific location. Other sensing elements are distant from the main grouping of sensing elements at the center of the drive windings to measure relatively distant material properties, such as the base material properties for plates at a lap joint or a weld. The use of relatively small sensing elements, e.g., down to 1 mm by 1 mm (0.04 in. by 0.04 in.) or smaller squares in an array, permits high resolution imaging of absolute properties. High resolution imaging is critical for detection of small cracks, while absolute imaging is critical to correct robustly for lift-off variations and to provide reliable crack responses for cracks that form in clusters, as is typical for cracks in the fretting regions of engine disk slots.

In an embodiment, the number of conductors used in the primary winding can be reduced further so that a single rectangular drive is used. As shown in FIG. 5, FIG. 21, and FIG. 22, a single loop having extended portions is used for the primary winding. A row of sensing elements 75 is placed on the outside of one of the extended portions. This is similar to designs described in U.S. Pat. No. 5,453,689 where the effective wavelength of the dominant spatial field mode is related to the spacing between the drive winding and sensing elements. This spacing can be varied to change the depth of sensitivity to properties and defects. Advantages of the design in FIG. 5 include a narrow drive and sense structure that allows measurements close to material edges and non-crossing conductor pathways so that a single layer design can be used with all of the conductors in the sensing region in the same plane. The width of the conductor 91 farthest from the sensing elements can be made wider in order to reduce an ohmic heating from large currents being driven through the drive winding. In addition, dummy sense elements 89 with substantially portions of the connection leads can also be used to help maintain the spatial distribution of conductors around the sense elements and to reduce edge effects for the outer elements of the array.

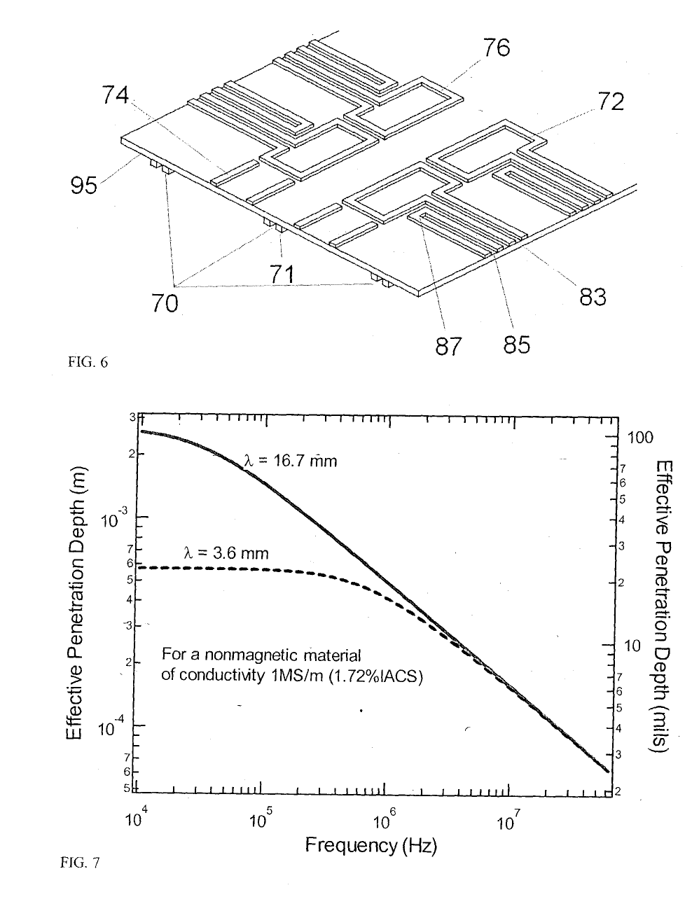

One complication in designing and fabricating the arrays is the need to bring out numerous leads from the sensing elements. This can be accomplished using connection leads as shown in FIG. 6 where the leads to each sensing element 83 are closely paralleled by another set of leads 85 ending in a closed loop 87. This flux cancellation lead design, as described in U.S. patent application Ser. Nos. 09/666,879 and 09/666,524, has the differential response between the actual sensing element 83 and the parallel leads 85 measured. This lead design permits direct cancellation of contributions from the leads of the sensing elements to the voltage measured at the terminals of these elements. The resulting capability to use long leads permits simple and low-cost microfabrication methods and connector designs to be used. This, in turn, improves sensor connector durability, while substantially reducing sensor replacement costs. In this design the primary windings 70 are separated from the secondary element arrays 72 and 76 by a layer of insulation 95. This layer of insulation is typically 0.5 to 1 mil (12.7 to 25.4 micrometers) thick Kapton™. The central drive winding 71 can also be placed on the same side of the insulating layer 95 as the sense elements 72 and 76. Other similar lead designs might be used on two layers to similarly cancel the flux. For example, instead of bringing the flux cancellation leads 85 back on the same layer along side the sensor leads 83, they could travel in the second layer on top of the sensor leads again canceling the flux contribution from the leads.

The MWM sensor and sensor array structure can be produced using micro-fabrication techniques typically employed in integrated circuit and flexible circuit manufacture. This results in highly reliable and highly repeatable (i.e., essentially identical) sensors, which has inherent advantages over the coils used in conventional eddy-current sensors. As indicated by Auld and Moulder, for conventional eddy-current sensors “nominally identical probes have been found to give signals that differ by as much as 35%, even though the probe inductances were identical to better than 2%” [Auld, 1999]. This lack of reproducibility with conventional coils introduces severe requirements for calibration of the sensors (e.g., matched sensor/calibration block sets). In contrast, duplicate MWM sensor tips have nearly identical magnetic field distributions around the windings as standard micro-fabrication (etching) techniques have both high spatial reproducibility and resolution. The sensor response can be accurately modeled which dramatically reduces calibration requirements. For example, calibration in air can be used to measure an absolute electrical conductivity without calibration standards. The windings are typically mounted on a thin and flexible substrate, producing a conformable sensor. The insulating layers can be a flexible material such as Kapton™, a polyimide available from E. I. DuPont de Nemours Company.

The single layer designs of the drive and sensing elements supports low cost fabrication without introducing excessive requirements to align multiple layers. This significantly reduces manufacturing costs and increases the number of suppliers that can fabricate the sensors. However, to obtain reasonable signal to noise levels for such single turn coils (simple rectangles) at low frequencies, it is necessary to apply more current than is typical for conventional eddy current sensors, e.g., over 1 A. Fortunately, at the high frequencies used for surface-breaking flaws in engine components (e.g., 5 MHz to 32 MHz), there is plenty of signal, even for a single turn coil without requiring such high drive currents. One practical limitation on the sensing element size is fabrication costs (e.g., 75 μm line widths and larger are low cost with many suppliers, while smaller line widths is more costly and limits available suppliers). Another limitation is the relative contribution to the signal of the flux coupled by the active sensing area to the flux coupled by the relatively long leads. Thus, these leads are kept close together and the novel “flux cancellation” design is used to literally cancel the contribution from these long leads (thus instead of two conductors entering each sensing element, there are actually four conductors—two to sense the flux linked by the sensing elements and the leads themselves, and the other two to cancel the contribution from the leads, leaving just the response of the sensing elements).

For eddy current sensors operating at high frequencies, the induced eddy currents are confined to a thin layer (due to the skin effect) near the surface, while at low frequencies this layer penetrates deeper into the material under test where it is limited by the sensor geometry. For MWM sensors and MWM-Arrays, the depth of penetration of the magnetic field into the material under test at lower frequencies is also limited to a fraction of the drive winding spatial wavelength, λ. The depth of penetration of magnetic fields into titanium or nickel alloys at higher frequencies is approximately equal to the conventional skin depth δ=(2/ωμσ)^{1/2}, where ω=2πf is the angular frequency for frequency f, μ is the magnetic permeability, and σ is the electrical conductivity. For lower frequencies, the MWM field depth of penetration for each spatial Fourier mode n is 1/Re(Γₙ), where

$${Γ}_{n} = \sqrt{{k}_{n}^{2} + j ωμσ} = \sqrt{{( 2 π n / λ )}^{2} + j 2 / {δ}^{2}}$$

kₙ=πn/λ is the spatial mode number, and λ is the spatial wavelength of the drive winding (Goldfine, 1993). The fundamental spatial mode (n=1) has the greatest depth of penetration, with a spatial wavelength equal to λ. This spatial wavelength is taken as two times the spacing between the linear drive segments and is similar to that of a coil with a diameter approximately equal to the half wavelength. For the same drive current frequency the magnetic fields from a longer wavelength (e.g., 16.7 mm) sensor will penetrate deeper into the material under test than the fields from a shorter wavelength (e.g., 3.6 mm) sensor. As shown in FIG. 7, this is true at relatively low frequencies, e.g., under 1 MHz for titanium or nickel alloys. Over 10 MHz, the wavelength does not significantly affect the depth of penetration of the fields.

For the MWM and MWM-Arrays, the sensor response at each sensing element is typically obtained in terms of the magnitude and phase (or real and imaginary part) of the transinductance. The transinductance is equal to the transimpedance divided by the angular frequency, ω=2πf, where f is the frequency of the applied drive winding current. The transimpedance is the voltage measured at the two terminals of the sensing elements vₛ divided by the applied current i_{d}.

$$transimpedance = \frac{sensing element voltage}{drive winding current} = \frac{{𝓋}_{s}}{{i}_{d}}$$

For the original MWM sensor of FIG. 1a, the sensing element voltage is the sum of the voltages induced on each set of meandering secondaries. The transinductance is then

$$transinductance = \frac{transimpedance}{j2π f} = \frac{{𝓋}_{s}}{j2π f {i}_{d}}$$

where j=(−1)^{1/2}. The transinductance has the units of inductance and reflects the inductive coupling between the drive winding and sensing elements.

Any model-based nondestructive testing approach requires that the sensor behavior match the model predictions for the material under test. Furthermore, to be practical, each individual sensor should be essentially identical. The MWM was designed to provide responses that matched the behavior of analytical models derived from basic physical principles. In contrast, eddy current sensors are typically designed to be very sensitive and then the response is modeled without trying to redesign the sensor to reduce the error between the actual and predicted response (Dodd, 1982). One benefit of designing the sensor to match a model is a simplified calibration procedure. To calibrate, a measurement is simply performed in air, away from any conducting or magnetic media. This “air calibration,” described in U.S. Pat. No. 6,188,218, corrects for variations in cable capacitance, unmodeled inductive coupling and drift in instrumentation. Most importantly, this air calibration permits the measurement of absolute electrical properties that are robust and can reflect, for example, microstructure of the material under test. These measurements are often directly comparable to literature values for the material properties. As part of the calibration, measurements are sometimes also performed with a “shunt” sensor that has the connection leads at the sense element shorted together. This provides a direct measurement of the parasitic effect of the leads on the measurement response. Preferably, the shunt measurement is performed with the shunt sensor on the component, or a part with similar properties as the component, to be inspected so that the calibration conditions mimic the inspection conditions as well as possible. In addition, it is sometimes helpful to perform shunt measurements both in air and on the part.

Scanning arrays provide imaging of flaws in metallic components. For example, MWM-Array images revealed distributed microcracks, small cracks and visible macrocracks in an aluminum four-point bending fatigue specimen as described in U.S. patent application Ser. No. 10/345,883. Images can be obtained with the sensor in different orientations. The MWM-Array is most sensitive to cracks that are oriented perpendicular to the linear drive segments (note that the induced eddy currents are dominantly in the direction of the longer linear drive segments). The MWM remains sensitive to cracks oriented as much as 75 degrees from this perpendicular orientation and even higher in the case of macrocracks and EDM notches. EDM notches can be easily detected even when they are parallel to the drive windings, which is the disadvantage of EDM notches for demonstrating sensitivity. Because they are not as tight as real cracks, they can be detected at all orientations. Since the array is sensitive to cracks that are as much as 75 degrees away from the perpendicular orientation, two scans can be performed, with drive winding orientations that differ by at least 15 degrees, to detect cracks in all orientations.

Sensor arrays can also be designed to provide measurements at two or more different orientations so that a single pass of the sensor array is required, which also improves throughput. An example is the sensor design of FIG. 26, which shows a drive winding 105 configured to provide two different orientation angles when scanned over a material surface. One linear array of sense elements 107 are at a different angle than a second linear array of sense elements 109, which ensures that all crack orientations are covered.

Deep penetration sensors, which have a longer spatial wavelength, provide the capability to image hidden geometric features in engine components, measure wall thickness in turbine blades, and the ability to manually scan wide areas and build high resolution images without expensive scanners. This ability to detect subsurface damage, demonstrated for hidden corrosion damage, described in U.S. patent application Ser. No. 10/345,883, is also useful for detection of subsurface anomalies in engine disks, such as buried inclusions.

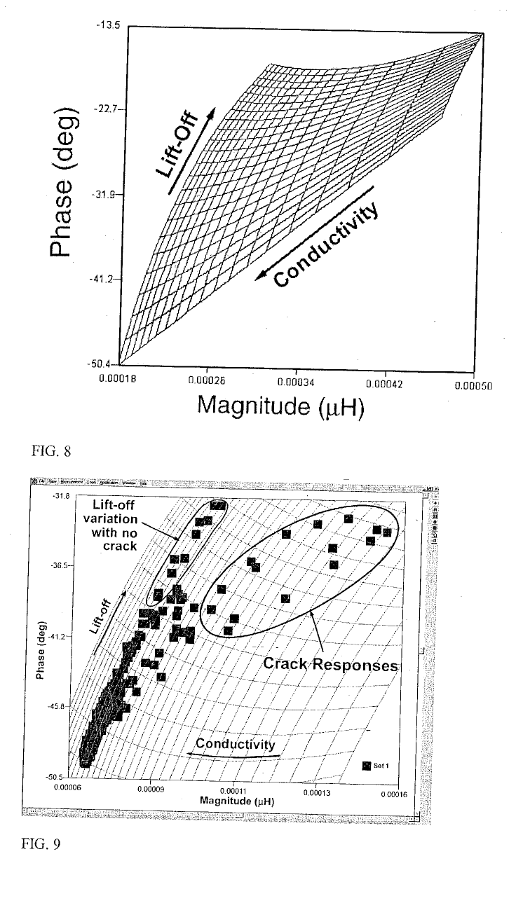

An efficient method for converting the response of the MWM sensor into material or geometric properties is to use grid measurement methods. These methods map the magnitude and phase (or real and imaginary parts) of the sensor impedance into the properties to be determined and provide for a real-time measurement capability. The measurement grids are two-dimensional databases that can be visualized as “grids” that relate two measured parameters to two unknowns, such as the electrical conductivity (or magnetic permeability) and lift-off (where lift-off is defined as the proximity of the MUT to the plane of the MWM windings). For the characterization of coatings or surface layer properties, three- (or more)-dimensional versions of the measurement grids called lattices and hypercubes, respectively, can be used. Alternatively, the surface layer parameters can be determined from numerical algorithms that minimize the error between the measurements and the predicted responses from the sensor. An advantage of the measurement grid method is that it allows for real-time measurements of the absolute electrical properties of the material and geometric parameters of interest. The database of the sensor responses can be generated prior to the data acquisition on the part itself, so that only table lookup operation, which is relatively fast, needs to be performed. Furthermore, grids can be generated for the individual elements in an array so that each individual element can be lift-off compensated to provide absolute property measurements, such as the electrical conductivity. This again reduces the need for extensive calibration standards. In contrast, conventional eddy-current methods that use empirical correlation tables that relate the amplitude and phase of a lift-off compensated signal to parameters or properties of interest, such as crack size or hardness, require extensive calibrations and instrument preparation. A representative measurement grid for a low-conductivity nonmagnetic metal (e.g., titanium alloys, some superalloys, and austenitic stainless steels) is illustrated in FIG. 8.

FIG. 9 shows an example of a measurement grid used to estimate the conductivity and lift-off for a high conductivity nonmagnetic metal (e.g., aluminum alloy). In this case, the model assumed that the material under test (MUT) was an infinite half space (i.e., a single layer of infinite thickness). This is a reasonable assumption when the skin depth is small compared to the actual thickness of the material under test (as for an engine disk slot). It also assumed an air gap (or insulating layer) exists between the sensor and the first conducting surface. This “air gap” is called the lift-off. The data shown in FIG. 9 is for a single channel (sensing element) of an MWM-Array as it is scanned across a surface. For more complicated problems, such as a crack under a coating on a turbine blade, the two unknowns might be the lift-off and the conductivity of the substrate, using a three-layer model (i.e., the lift-off gap is one layer, the coating is a second layer, and the substrate is a third, infinitely thick layer). Alternatively, two or more frequencies can be used with multi-dimensional databases (e.g., lattices or hypercubes) to estimate more than two unknown properties. A typical frequency used in single frequency measurements of engine disk slots is 6.3 MHz. This frequency is sufficient for detection of the 1.5 mm (0.06 in.) long cracks. However, for smaller cracks in other more critical locations operation at significantly higher frequencies may be required. For crack detection and length, location, and depth determination multiple frequency methods can be used.

For measuring the response of the individual sensing elements in an array, multiplexing between the elements can be performed. However, this can significantly reduce the data acquisition rate so a more preferably approach is to use an impedance measurement architecture that effectively allows the acquisition of data from all of the sense elements in parallel. To perform absolute measurements of material properties, to robustly correct images for lift-off variations caused by varying surface roughness and curvature, and to develop reliable multiple frequency crack response signals, it is essential to generate robust impedance data across multiple frequencies and across wide ranges of impedance magnitude and phase. This type of instrument is described in detail in U.S. patent application Ser. No. 10/155,887, filed May 23, 2002, the entire teachings of which are incorporated herein by reference. This instrumentation can acquire data from 39 fully parallel impedance channels (magnitude and phase) simultaneously in less than 10 milliseconds (e.g., 100 measurements per second on 39 channels simultaneously). This speed is critical for increasing throughput rates for inspection of wide areas such as the entire internal surface of an engine disk slot, or a bore, a web region, or a high aspect ratio bolt hole in an engine disk. To perform measurements with the grid methods and air calibration, each channel must provide a robust and accurate measurement of absolute impedance. The use of multiple sensing elements with one meandering drive and parallel architecture measurement instrumentation then permits high image resolution in real-time.

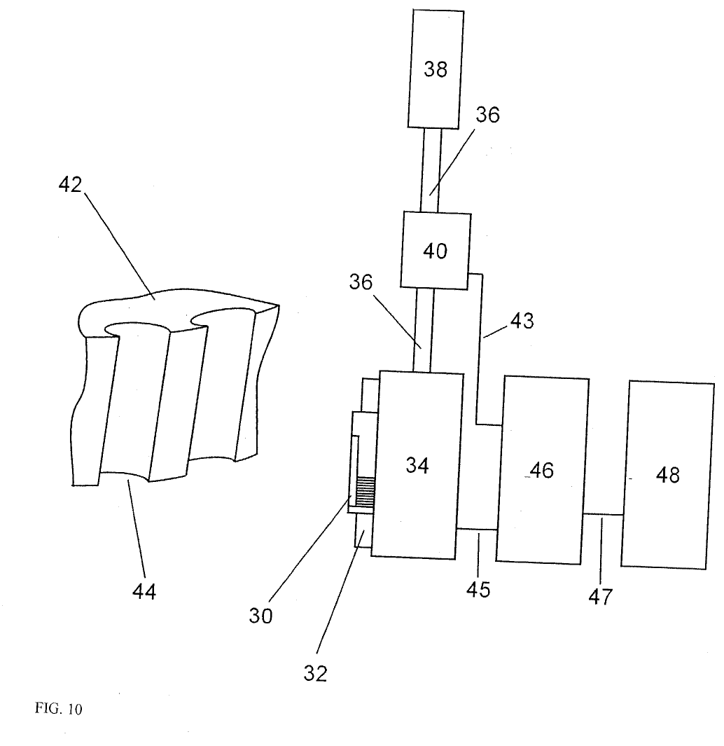

FIG. 10 provides an illustration of an MWM-Array probe configured for slot inspection. The flexible MWM-Array 30 is placed in the slot 44 of the disk 42 with a support 32. The support can be rigid or can include conformable components such as an inflatable balloon as described in U.S. patent application Ser. No. 10/172,834, filed Jun. 13, 2002, the entire teachings of which are incorporated herein by reference. The inflatable balloon can be filled with water to provide pressure behind the sensor and can improve sensor durability (i.e., by deflating the balloon prior to entry into the slot). The support 32 can be attached to probe electronics 34, which provide amplification of the sense element signals, a shaft 36, which guides the scan direction for the sensor, and a balloon inflation mechanism 38. A position encoder 40 provides longitudinal registration of the MWM-Array data along the axis of the inspected slot. The sensing elements positions (with 0.04 in. spacing) provide the position in the transverse direction, resulting in a fully registered two-dimensional image, with manual scanning using an single, axial, position encoder. The electrical signals are monitored with the parallel architecture data acquisition impedance instrumentation 46 through electrical connections from the probe electronics 45 and the position encoder 43. A connection 47 between the impedance instrument and a processor 48, such as a computer, is used to control the data acquisition and process and display the data.

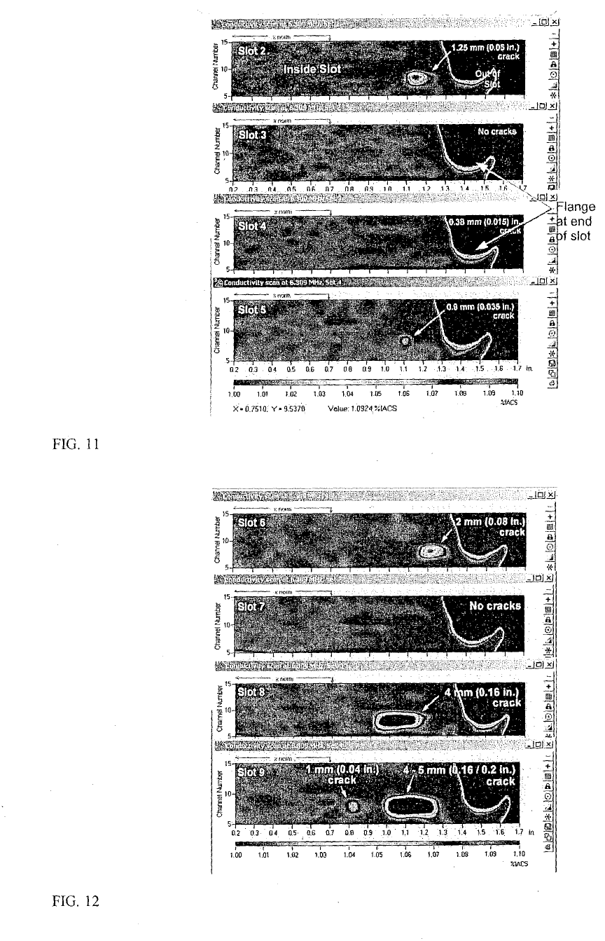

This probe has the capability to inspect both the lower and upper quadrant of the slot on one side in a two step process. The process involves manually pressing a button that conveniently and quickly shifts the encoder configuration to support scanning the bottom quadrant of the slot side beginning at the center and then returning to the center, pressing the button, and scanning the upper quadrant of the slot side. This design requires the operator to flip over the disk to then inspect the upper and lower quadrants of the opposite side of the slots. Alternatively, the MWM-Array can be designed to permit scanning of both sides simultaneously, without flipping over the engine disk, permitting rapid scanning of both sides in either a manual or automated operation. The use of balloons that are deflated upon entry into the slot often extends the life of the sensors by limiting damage upon entry into the slot. Also, combinations of balloons and foam with plastic can often improve conformability to complex slot geometries. FIG. 11 and FIG. 12 provide typical conductivity images obtained from engine slots with fretting damage. Slots 2 through 9 of this F-110 engine disk were selected because they contain several cracks in the range from 0.38 mm (0.015-in.) to 5.1 mm (0.20-in.), with six documented cracks under 2.5 mm (0.1-in.) based on acetate replicas. In this case, the objective was to reliably detect cracks 1.5 mm (0.06-in.) and longer with reasonable false alarm rates. As shown in FIG. 11 and FIG. 12, cracks 1.25 mm (0.05-in.) and longer provide large indications easily visualized in the two-dimensional images (C-scans) with no background indications even approaching their signal level. The two smaller cracks 0.9 mm (0.035-in.) long in slot 5 and 1.0 mm (0.04-in.) long in slot 9 produce significant signals, however, these are well below the required detection threshold so no attempt was made to enhance their detection. The single frequency measurements shown here may produce false positive indications if the smaller crack images are enhanced.

Two processing steps were performed on the MWM-Array transinductance data. The first was to convert the transinductance real and imaginary parts into absolute electrical conductivity and lift-off images using the grid measurement methods. The resulting conductivity images are then corrected for lift-off variations away from the cracks. However, since the cracks themselves were not modeled in this case, the lift-off correction at the crack location is not an exact correction. The second processing step was to normalize the response by adjusting each sense element. The adjustment may involve dividing each sense element response by the average response for each element where the average is taken over a specified area within the slot that does not contain a crack. The response may then be rescaled (e.g., multiplied) by the average response for all of the sense elements or a specified value. The adjustment may also involve subtraction of the average response or some other pre-selected level. The images are then presented with a color scale selected intentionally to emphasize cracks longer than 1.25 mm (0.05-in.) and to suppress smaller cracks and background variations.

As another alternative, other crack signature enhancement tools can also be applied. For example, as described in U.S. patent application Ser. No. 10/345,883, filed Jan. 15, 2003, the entire teachings of which are incorporated herein by reference, a combination of multiple frequencies and spatial matched filters can enhance the crack responses and suppress clutter (non-crack like background signals). This would improve detection thresholds but may limit robustness to certain types of cracks. Care must be taken when “optimizing” detection filters on a specific training set or even test set of cracks that may not completely represent the population of possible cracks in service run hardware.

For the images of FIG. 11 and FIG. 12, a calibration was performed in air with no calibration standards. At overhaul facilities, detection thresholds would be set based on results obtained from a training set of actual disk specimens with real cracks ideally formed in service. Calibration takes approximately 15 seconds, not including initial system warm-up and setup time of about fifteen minutes. Scans take less than one minute per slot. The elimination of expensive scanners and the increase in throughput compared to single coil inspection methods (that typically take 10 to 20 minutes per slot) offer substantial cost savings potential.

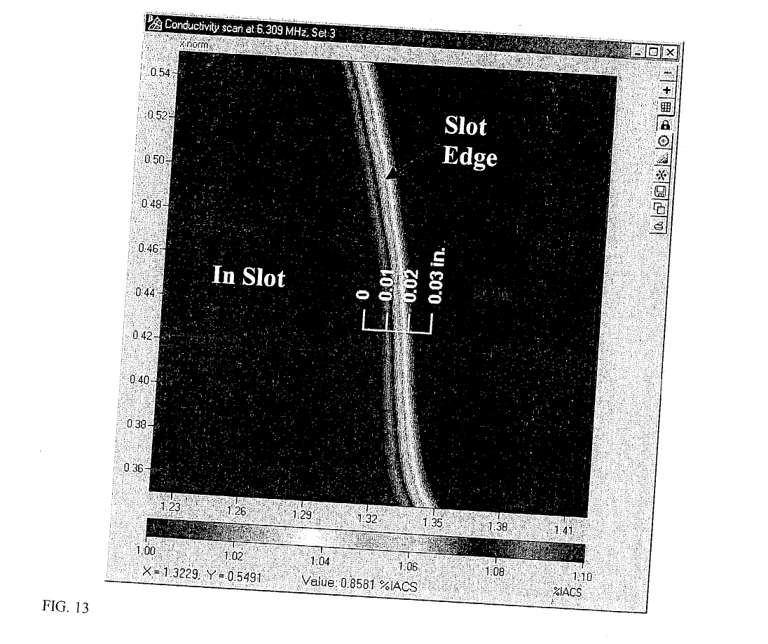

Another feature evident in the scan images of, for example, FIG. 11 is the flange at the edge of the slot. FIG. 13 provides an expanded view of the edge signature. The effective width of this edge is less than 0.5 mm (0.02-in.) in the lift-off corrected conductivity images. Thus, for F-110 engine disks the capability to reduce the edge signature to less than 0.5 mm (0.02-in.) combined with the capability to detect cracks longer than 1.0 mm (0.04-in.) satisfies the inspection requirement for detecting cracks longer than 1.5 mm (0.06-in.) within the slot. This capability to minimize the edge signature results from both the small sensing element size and the use of the balloon to provide even and consistent pressure on the MWM-Array sensing elements as the sensor moves off the edge.

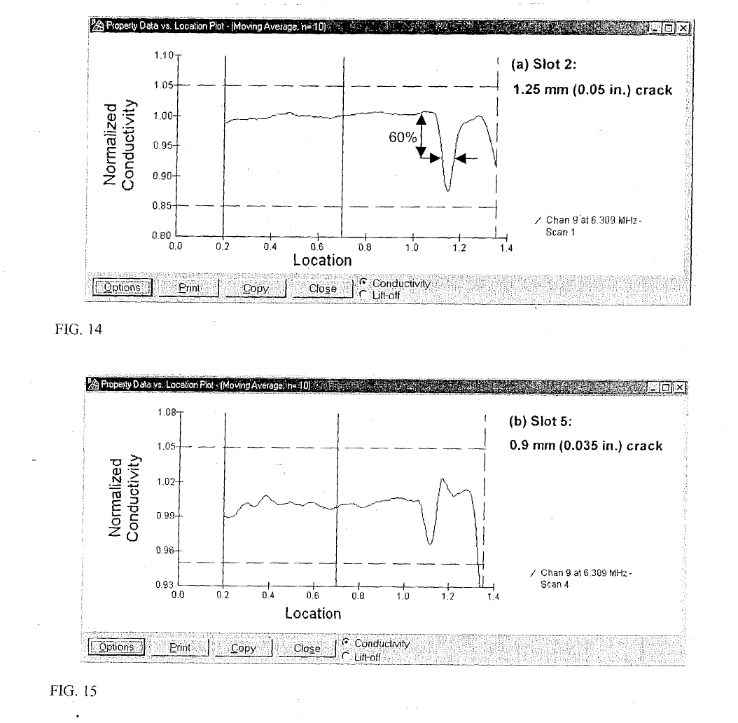

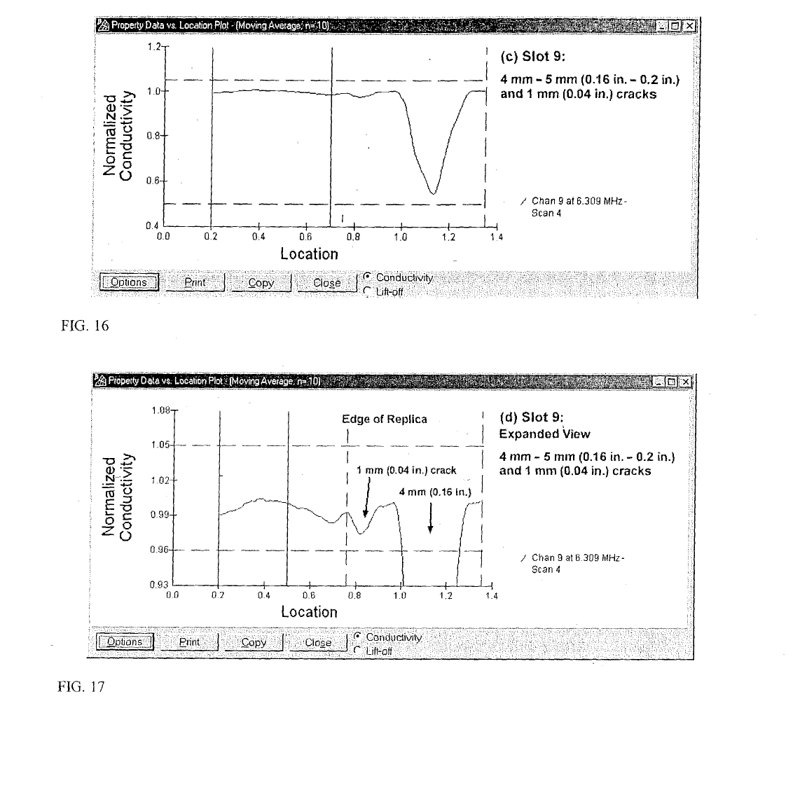

FIG. 14 though FIG. 17 provide the corresponding individual channel (sensing element) responses (B-scans) for slots 2, 5, and 9 in one of the disks. Only the response from the channel that passes over the crack is plotted. Repeated measurements within these slots continually produce similar results. Even the background variations appear repeatable. In Slot 9 there are two significant crack indications as shown in FIG. 17. FIG. 9a shows a plot of the estimated crack length compared to the actual crack length determined from acetate replicas taken in the slots, as described earlier. FIG. 9b provides a similar plot of the estimated distance from the slot edge to the nearest tip of the first crack detected within the slot.

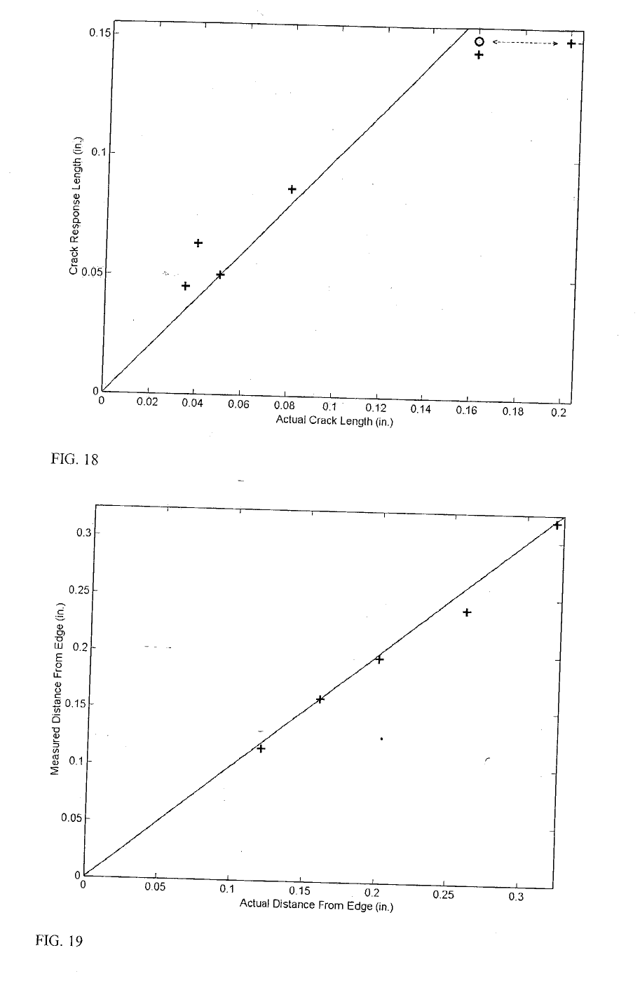

The effective property measurements made with the MWM-Array can also be used to determine the crack length and location within the slot. As a demonstration of this capability, the 1.25 mm (0.05-in.) long crack in slot 2 was used as the training set. As shown in FIG. 14, the width of the crack response at a specific percentage of the normalized conductivity response was used to estimate the crack length. The percentage of the response height at which the width of the crack response matched the documented crack length for the training set crack was used. In this case, the response width matched the length of the 1.25 mm (0.05-in.) long crack at sixty percent (60%) of the response height. Note that this is a simple example and several cracks could be used in the training set, but setting this percentage this would not have to be performed at each inspection; it would be performed only once for a given sensor and inspection application. Thus, the response width at 60% of the response height was used to estimate the length of the other cracks in the eight inspected slots. FIG. 18 shows the crack length estimation results for these cracks. A relatively linear response exists for the six documented cracks in these eight slots. The longest crack at 5.0 mm (0.2-in.) was actually comprised of a principal crack about 4.1 mm (0.16-in.) long, which agrees well with the MWM response, and a very tight extension of this crack that is only visible under a microscope. Consequently, this crack is indicated here by two symbols. The 1.0 mm (0.04 in.) crack in slot 9 is slightly out of line. This crack was between the larger crack and another apparent crack slightly farther into the slot that was not completely documented with acetate replicas. The crack may have actually been longer than determined from the replica if, for example, there was a tight extension as with the 5.0 mm (0.2-in.) long crack in the same slot.

FIG. 19 provides the crack location in terms of the distance from the slot edge to the nearest tip of the first crack detected within the slot. The agreement here is more consistent because the effect of “tight extended cracks” over these longer distances is less apparent than on shorter distances for the crack length plot of FIG. 18. The two-dimensional images clearly indicate the edge and illustrate the high resolution imaging capability of the MWM.

As another alternative embodiment, in addition to inductive coils, other types of sensing elements, such as Hall effect sensors, magnetoresistive sensors, SQUIDS, and giant magnetoresistive (GMR) sensors, can be used in place of, or in combination with, inductive coils. The use of GMR sensors for characterization of materials is described in more detail in U.S. patent application Ser. No. 10/045,650, the entire teachings of which are hereby incorporated by reference.

As a validation of sensor performance, an MWM-Array was used to perform a limited POD study on titanium alloy ENSIP flat specimens. The flat specimens were selected by an original equipment manufacturers (OEM) to be representative of the ENSIP flat specimens used in other POD studies. For this study, a two-frequency method (8 and 12 MHz) was used. Reducing the sensing element footprint and using more (e.g., three) and higher (up to 32 MHz) frequencies can improve sensitivity for smaller cracks.

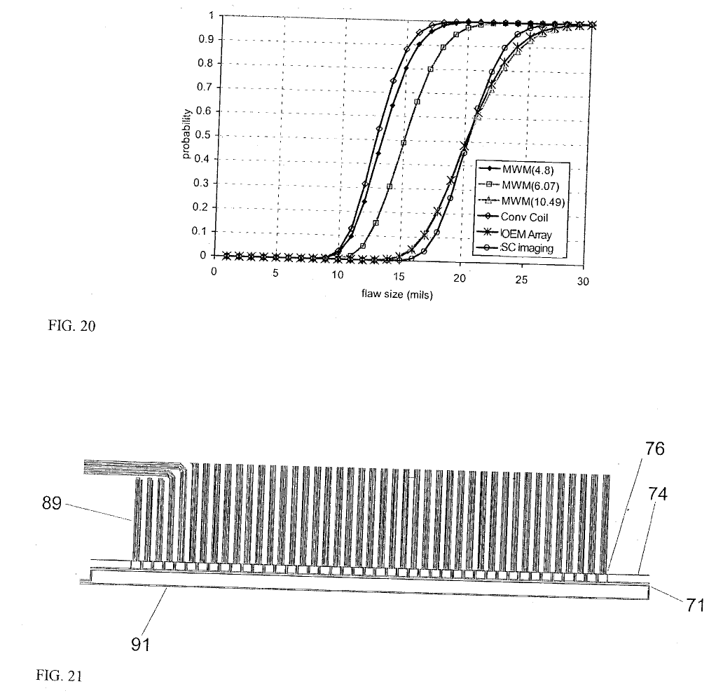

The results of the POD study with comparisons of the MWM-Array results to (1) a standard eddy current sensor and (2) an OEM conformable eddy current array (both with differential coil designs) are provided in FIG. 20. The ENSIP flat specimens used in this study were selected to demonstrate relative detection capability. A set of fourteen ENSIP Ti 6-4 specimens containing six cracks each were used for initial testing. The crack length in this set varied from 0.1 to 1.5 mm (0.004 to 0.058-in.). Four specimens containing 23 cracks were selected by the OEM for blind tests at the OEM facility. The MWM-Array results shown here are for three different detection threshold settings. The false alarm rate for the MWM, in each case, is less than 5%. When comparing probability of detection performance, care should be taken to set false alarm rates at identical levels. Robust comparison of different technologies requires detailed knowledge of each method's detection algorithms and all recorded false alarms. For example, if a larger footprint sensor is compared to a smaller footprint sensor, there is inherent averaging with the larger sensor that may reduce the number of false alarm opportunities. This would require the false alarm rates to be scaled accordingly to provide a fair POD comparison. Since this is not common practice, only general conclusions can be drawn from such limited POD studies. The false alarm information was not available in this for all sensors tested. Nevertheless, the results of the limited POD study presented in FIG. 20 demonstrate representative inspection reliability for the MWM-Array.

The lack of available fabricated test specimens with simulated or real cracks in regions with fretting damage makes qualification of NDE methods using accepted POD study methods difficult. One approach, however, is to use a substantial set of available specimens with real cracks from service-run hardware that has been removed from service after detection of cracks. Fortunately, for the specific engine disks addressed herein, there is a substantial supply of such service-run disks. Also, disks that have large cracks tend to have some smaller cracks as well. The result is a substantial population of slots with cracks and slots with no cracks with varying degrees of fretting damage. While it is important to use actual field-induced damage for inspection reliability demonstrations, whenever possible, to accurately represent crack morphology, local geometry, and surface conditions such as fretting, it is important to recognize that there is a potential for cracks to exist in this hardware that are not detected by any present nondestructive techniques.

Surface roughness can be measured as well using the relationship between lift-off and R_{A}. This is described in the NASA Phase II final report titled “Nondestructive Characterization of Thermal Spray Coating Porosity and Thickness”, dated Sep. 17, 1997 and in U.S. Provisional Application No. 60/065,545, filed Nov. 14, 1997, the entire teachings of which are incorporated herein by reference. This lift-off image/data can be thresholded or analyzed to accept or reject disks based on fretting damage. Furthermore, the lift-off level can be used to adjust confidence levels for crack detection since sensitivity to cracks is reduced as lift-off increases.

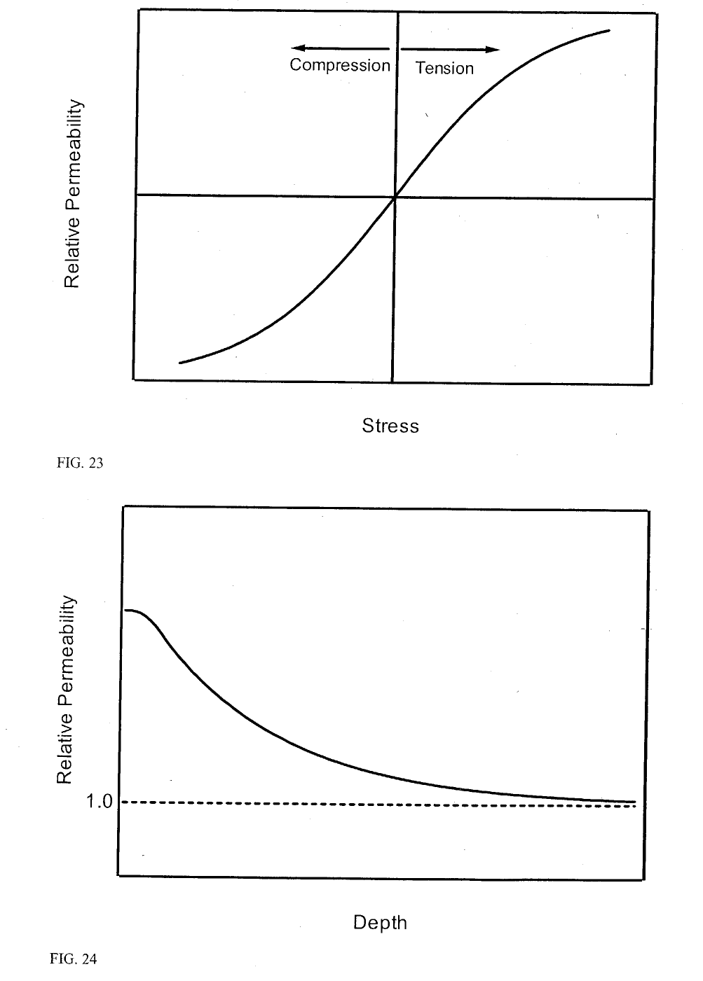

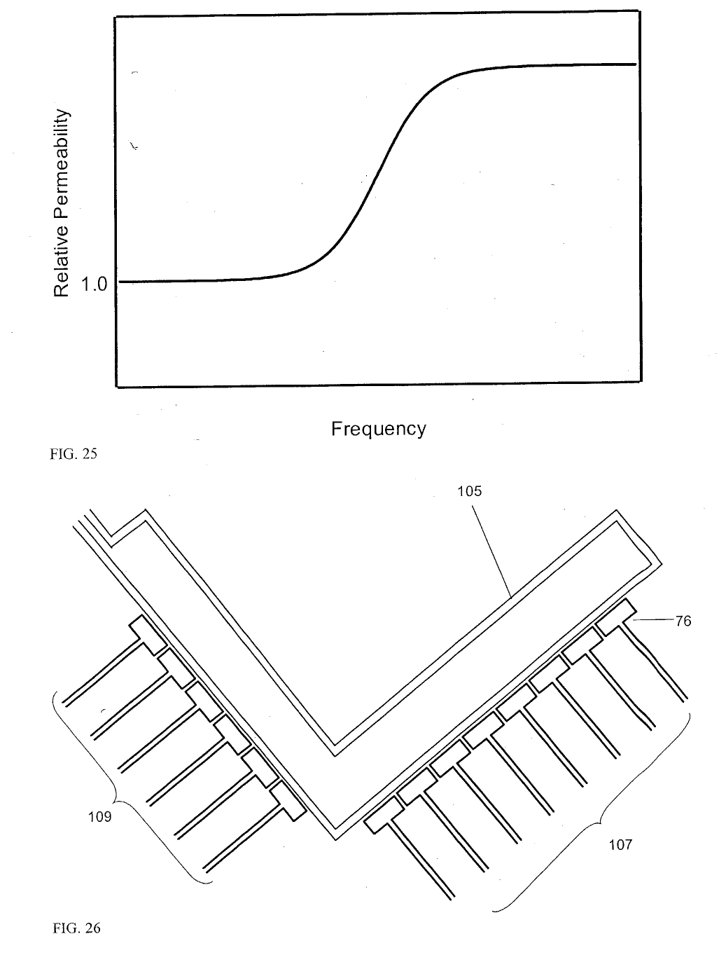

For nickel alloy engine materials, such as Alloy 738 or Alloy 718, shot peening and/or heat treatment may produce near surface relative permeability greater than 1.0. FIG. 23 shows a schematic plot relating the relative magnetic permeability to the compressive and tensile stresses in the material. The nominal variation of the magnetic permeability with depth is illustrated in FIG. 24 and indicates the region of higher permeability near the surface caused by the shot peening and/or heat treatment process. FIG. 25 shows the corresponding variation in the relative permeability measurement as a function of frequency. At sufficiently high frequencies, the magnetic field is confined near the surface of the MUT and reflects only the permeability (and stress) of the surface region. At lower frequencies, the magnetic field can penetrate through this region and the average or effective permeability is reduced. At sufficiently low frequencies, the magnetic field penetrates far enough into the base material that the permeability approaches 1.0. High resolution images of permeability can then be used to map residual stress variations to qualify shot peening or other manufacturing processes or to assess material aging/material degradation, as described in more detail in U.S. patent application Ser. No. 10/351,978, filed Jan. 24, 2003, the entire teachings of which are incorporated herein by reference. Then, regions with unacceptable residual stresses might be reworked (e.g., blending and reshot peening) to extend life.

While the inventions have been particularly shown and described with reference to preferred embodiments thereof, it will be understood to those skilled in the art that various changes in form and details may be made therein without departing from the spirit and scope of the invention as defined by the appended claims.

References incorporated by reference in their entirety:

Auld, B. A. and Moulder, J.C. (1999), “Review of Advances in Quantitative Eddy-Current Nondestructive Evaluation,” Journal of Nondestructive Evaluation, vol. 18, No. 1.

Dodd, C., and W. Deeds (1982), “Absolute Eddy-Current Measurement of Electrical Conductivity,” Review of Progress in Quantitative Nondestructive Evaluation, Vol. 1, 1982. Plenum Publishing Co.

Goldfine, N. (1993), “Magnetometers for Improved Materials Characterization in Aerospace Applications,” Materials Evaluation Vol. 51, No. 3, pp. 396-405; March 1993.

MIL-HDBK-1823 (1999), “Nondestructive Evaluation System Reliability Assessment,” Department of Defense Handbook, Apr. 30, 1999.

The following references are also incorporated herein by reference in their entirety.

NASA Phase II Proposal, titled “Shaped Field Giant Magnetoresisitive Sensor Arrays for Materials Testing,” Topic #01-II A1.05-8767, dated May 2, 2002

Navy Phase I Proposal, titled “Observability Enhancement and Uncertainty Mitigation for Engine Rotating Component PHM,” Topic #N02-188, dated Aug. 14, 2002.

NASA Phase I Proposal, titled “Non-Destructive Evaluation, Health Monitoring and Life Determination of Aerospace Vehicles/Systems,” Topic #02-H5.03-8767, dated Aug. 21, 2002.

Final Report submitted to FAA, titled “Crack Detection Capability Comparison of JENTEK MWM-Array and GE Eddy-current Sensors on Titanium ENSIP Plates”, dated Sep. 28, 2001, Contract #DTFA03-00-C-00026, option 2 CLIN006 and 006a.

NASA Phase II Final Report, titled “Nondestructive Characterization of Thermal Spray Coating Porosity and Thickness”, dated Sep. 17, 1997, Contract #NAS5-33212.

Technical paper titled “Residual and Applied Stress Estimation from Directional Magnetic Permeability Measurements with MWM Sensors,” published in ASME Journal of Pressure Vessel Technology, Volume 124, pp 375-381; August 2002.

Technical paper titled “Fatigue and Stress Monitoring Using Scanning and Permanently Mounted MWM-Arrays,” presented at 29th Annual Review of Progress in QNDE; Bellingham, Wash.; July 2002.

Technical paper titled “Absolute Electrical Property Imaging using High Resolution Inductive, Magnetoresistive and Capacitive Sensor Arrays for Materials Characterization,” presented at 11^{th} International Symposium on Nondestructive Characterization of Materials, Berlin, Germany; June, 2002.

Technical paper titled “Application of MWM® Eddy-Current Technology during Production of Coated Gas Turbine Components,” presented at 11^{th} International Symposium on Nondestructive Characterization of Materials, Berlin, Germany; June 2002.

Technical presentation slides “Condition Assessment of Engine Component Materials Using MWM-Eddy-current Sensors,” ASNT Fall Conference, Columbus, Ohio; October 2001.

What is claimed is:

1. An apparatus for inspection of materials, said apparatus comprising:
a flexible sensor having at least one row of aligned sense elements for scanning across a material under test surface, individual connections to each sense element, and at least one linear primary conductor segment positioned parallel to the sensing element rows for imposing a magnetic field when driven by a time varying electrical current;
an impedance measurement instrument with dedicated electrical circuitry for each sense element;
means for recording sensor position over the material; and
means for converting sense element response into an effective property.

2. The apparatus as claimed in claim 1 wherein the sense elements are rectangular absolute sensing coils.

3. The apparatus as claimed in claim 1 wherein the sense element connections include a nearby pair of conductors to compensate for the connections' effect on the measured response of each sense element.

4. The apparatus as claimed in claim 1 wherein a primary conductor and the sense elements are in the same plane.

5. The apparatus as claimed in claim 1 wherein a primary conductor and the sense elements are in different planes.

6. The apparatus as claimed in claim 1 further comprising a second row of aligned sense elements on the opposite side of a primary conductor from the first row of sense elements.

7. The apparatus as claimed in claim 1 wherein the instrumentation performs data acquisition in parallel so that all channels are being monitored at the same time.

8. The apparatus as claimed in claim 1 further comprising a pressurizable support positioned behind the sensor array.

9. The apparatus as claimed in claim 1 wherein the material is inspected for cracks.

10. The apparatus as claimed in claim 9 wherein the material is scanned with the primary conductors perpendicular to the likely crack direction.

11. The apparatus as claimed in claim 9 wherein the material is scanned with the primary conductors at an angle to the likely crack direction.

12. The apparatus as claimed in claim 9 further comprising correlating an effective property to the crack length.

13. The apparatus as claimed in claim 9 further comprising using the effective property measurement to determine crack location.

14. The apparatus as claimed in claim 9 further comprising processing the effective property with a filter that matches a crack response.

15. The apparatus as claimed in claim 1 wherein the effective property is electrical conductivity.

16. The apparatus as claimed in claim 1 wherein the effective property is lift-off.

17. The apparatus as claimed in claim 1 wherein measurements are performed at multiple excitation frequencies.

18. A method for inspection of curved materials, said method comprising:
disposing a flexible sensor having at least one row of aligned sense elements for scanning across a material under test surface, individual connections to each sense element, and at least one linear primary conductor segment positioned parallel to the sensing element rows for imposing a magnetic field when driven by a time varying electrical current;
connecting each sense element to dedicated electrical circuitry in an impedance measurement instrument;
recording scan position over the material; and
and converting each sense element response into an effective property.

19. The method as claimed in claim 18 wherein the sense elements are rectangular absolute sensing coils.

20. The method as claimed in claim 18 wherein the sense element connections include a nearby pair of conductors to compensate for the connections' effect on the measured response of each sense element.

21. The method as claimed in claim 18 wherein a primary conductor and the sense elements are in the same plane.

22. The method as claimed in claim 18 wherein a primary conductor and the sense elements are in different planes.

23. The method as claimed in claim 18 further comprising a second row of aligned sense elements on the opposite side of a primary conductor from the first row of sense elements.

24. The method as claimed in claim 18 wherein the instrumentation performs data acquisition in parallel so that all channels are being monitored at the same time.

25. The method as claimed in claim 18 further comprising a pressurizable support positioned behind the sensor array.

26. The method as claimed in claim 18 wherein the material is inspected for cracks.

27. The method as claimed in claim 26 wherein the material is scanned with the primary conductors perpendicular to the likely crack direction.

28. The method as claimed in claim 26 wherein the material is scanned with the primary conductors at an angle to the likely crack direction.

29. The method as claimed in claim 28 further comprising scanning the material with a sensor at a different angle to the likely crack direction.

30. The method as claimed in claim 29 where the scan angles range between −45° and 30°.

31. The method as claimed in claim 26 further comprising correlating an effective property to the crack length.

32. The method as claimed in claim 26 further comprising using the effective property measurement to determine crack location.

33. The method as claimed in claim 26 further comprising processing the effective property with a filter that matches a crack response.

34. The method as claimed in claim 18 wherein the effective property is electrical conductivity.

35. The method as claimed in claim 18 wherein the effective property is lift-off.

36. The method as claimed in claim 18 wherein measurements are performed at multiple excitation frequencies.

37. The method as claimed in claim 18 further comprising calibrating the sensor by measuring the response of the sensor on a nonconducting material.

38. The method as claimed in claim 37 further comprising calibrating the sensor by measuring the response of a shunt sensor on a nonconducting material.

39. The method as claimed in claim 37 further comprising measuring the response of a shunt sensor on the test material as part of the calibration.

40. The method as claimed in claim 18 wherein the material is an engine disk slot.

41. A method for inspection of a slotted materials, said method comprising:
disposing a flexible sensor having at least one row of aligned sense elements for scanning across a material under test surface, individual connections to each sense element, and at least one linear primary conductor segment positioned parallel to the sensing element rows for imposing a magnetic field when driven by a time varying electrical current;
connecting each sense element to dedicated electrical circuitry in an impedance measurement instrument;
scanning the sensor along a side of the material;
recording scan position; and
converting each sense element response into an effective property.

42. The method as claimed in claim 41 further comprising a pressurizable support positioned behind the sensor array.

43. The method as claimed in claim 41 further comprising flipping the test material to inspect the opposite side.

44. The method as claimed in claim 41 further comprising a sensor array that permits scanning of both sides of the slot simultaneously.

45. A method for inspecting materials, said method comprising:
disposing a flexible sensor having at least one row of aligned sense elements for scanning across a material under test surface, individual connections to each sense element, and at least one linear primary conductor segment positioned parallel to the sensing element rows for imposing a magnetic field when driven by a time varying electrical current;
connecting each sense element to dedicated electrical circuitry in an impedance measurement instrument;
recording the scan position over the material;
converting each sense element response into an effective property; and
comparing the scan response to background responses having flaw signatures to determine a detection.

46. The method as claimed in claim 45 where the flaw is a crack.

47. The method as claimed in claim 45 where the background response is based on a model.

48. The method as claimed in claim 45 where the signature is from a simulated flaw.

49. The methods as claimed in claim 45 where the signature is from an actual flaw.

50. A method for inspecting engine disk slots, said method comprising:
disposing a flexible sensor having at least one row of aligned sense elements for scanning across a material under test surface, individual connections to each sense element, and at least one linear primary conductor segment positioned parallel to the sensing element rows for imposing a magnetic field when driven by a time varying electrical current;
connecting each sense element to dedicated electrical circuitry in an impedance measurement instrument;
recording the scan position over the material;
converting each sense element response into an effective property; and
correlating the effective property with a material state.

51. The method as claimed in claim 50 where the effective property is magnetic permeability.

52. The method as claimed in claim 51 where the material state is stress.

53. The method as claimed in claim 50 where the effective property is lift-off.

54. The method as claimed in claim 51 where the material state is surface roughness.

55. A test circuit comprising:
at least two rows of sense elements for scanning across a material under test surface, the sense elements in each row being aligned with one another;
at least one linear drive conductor segment positioned parallel proximate to each sense element row for imposing a magnetic field; and
means for measuring the response of each sense element.

56. A test circuit as claimed in claim 55 further comprising the drive conductor and sense elements are in the same plane.

57. A test circuit as claimed in claim 55 further comprising the drive conductor and sense elements are in the different planes.

58. A test circuit as claimed in claim 55 wherein the primary winding and sense elements are fabricated onto a flexible substrate.
